(19) United States
(12) Patent Application Publication
(10) Pub. No.: US 2011/0155236 A1
(43) Pub. Date: Jun. 30, 2011

(54) Nanowire Solar Cell and Manufacturing Method of the Same

(76) Inventors: Hajime Goto, Saitama (JP); Takashi Fukui, Hokkaido (JP); Junichi Motohisa, Hokkaido (JP); Kenji Hiruma, Hokkaido (JP)

(21) Appl. No.: 12/975,755

(22) Filed: Dec. 22, 2010

(30) Foreign Application Priority Data
Dec. 25, 2009 (JP) JP2009-295806

(51) Int. Cl. H01L 31/06; H01L 31/0352; B82Y 40/00

(52) U.S. Cl. 136/256; 438/93; 977/762; 257/E31.032

(57) ABSTRACT

To provide a solar cell enabling practical electric power to be obtained and excitons to be effectively collected, and a manufacturing method of the solar cell. A nanowire solar cell 1 comprises: a semiconductor substrate 2; a plurality of nanowire semiconductors 4 and 5 forming pn junctions; a transparent insulating material 6 filled in the gap between the plurality of nanowire semiconductors 4 and 5; an electrode 7 covering the end portion of the plurality of nanowire semiconductors 4 and 5; and a passivation layer 10 provided between the semiconductor 5 and the transparent insulating material 6 and between the semiconductor 5 and the electrode 7.

### CROSS-REFERENCE TO RELATED APPLICATION

This application is based upon and claims the benefit of priority from Japanese Patent Application No. 2009-295806 filed on Dec. 25, 2009, of which the contents are incorporated herein by reference.

### BACKGROUND OF THE INVENTION

1. Field of the Invention

The present invention relates to a nanowire solar cell comprising nanowire semiconductors, and a manufacturing method of the nanowire solar cell.

2. Description of the Related Art

Generally, a solar cell is known in which a planar pn junction surface is provided in parallel with the substrate surface. In recent years, a solar cell (hereinafter referred to as nanowire solar cell) comprising a fine linear semiconductor having a nano order diameter and referred to as a nanowire, a nanorod, and the like, is known in addition to the conventional common solar cell.

Further, in the nanowire solar cell, a technique is proposed in which the photoelectric conversion efficiency is improved by forming recessions and projections in the pn junction surface. It is considered that, in the nanowire solar cell in which the recessions and projections are formed in the pn junction surface, since the area of the pn junction surface is larger than the light receiving area, the effect of reducing the carriers, and the like, lost by the recombination is obtained and hence the photoelectric conversion efficiency is improved.

For example, a nanowire solar cell is proposed which is formed in such a manner that a p-type Si semiconductor is grown in the shape of nanowire by using gold fine particles as a catalyst, and that an i-type Si semiconductor layer and an n-type Si semiconductor layer are then formed on the p-type Si semiconductor along the shape of the p-type Si semiconductor (see, for example, B. Tian, X. Zheng, T. J. Kempa, Y. Fang, N. Yu, G. Yu, J. Huang and C. M. Lieber, “CoaXial Silicon nanowires as solar cells and nanoelectronic power sources”, Nature 449, 885-890 (2007); G. Zheng, W. Lu, S. Jin and C. M. Lieber, “Synthesis and Fabrication of High-Performance n-Type Silicon Nanowire Transistors”, Adv. Mater. 16, 1890-1893 (2004)).

The nanowire solar cell described in the document has a core shell structure, in which the p-type Si semiconductor is used as a core, and in which the i-type Si semiconductor layer and the n-type Si semiconductor layer are used as shells to be laminated on the p-type Si semiconductor, and hence has a pn junction surface with an area larger than a light receiving area. However, in the nanowire solar cell, only one nanowire is formed. Thus, there is a problem that a device capable of generating practical electric power cannot be manufactured with the nanowire solar cell.

Further, in the nanowire solar cell, the catalyst, such as gold, is used to grow the nanowire. Thus, there is a possibility that the catalyst metal element is incorporated in the nanowire as an impurity during the growth process. The incorporated catalyst metal element forms a deep level in the nanowire as the semiconductor, so as to promote recombination of excitons, and hence lowers the photoelectric conversion efficiency of the nanowire solar cell.

Further, the nanowire solar cell has a problem that, when the i-type Si semiconductor layer and the n-type Si semiconductor layer are formed as the shell layers, the temperature cannot be raised until the layers are epitaxially grown, and hence the i-type Si semiconductor layer and the n-type Si semiconductor layer are polycrystallized. The problem is due to the fact that, when the temperature is raised by heating to the epitaxial growth temperature, the catalyst metal is thoroughly incorporated into the nanowire of the p-type Si semiconductor layer serving as the core of the core shell structure. As a result of the low temperature epitaxial growth, the i-type Si semiconductor layer and the n-type Si semiconductor layer serving as the shell layers are formed into a structure including crystal grain boundaries. Since a plurality of dangling bonds existing in the crystal grain boundaries promote recombination of excitons, the sufficient photoelectric conversion efficiency cannot be obtained.

Further, a nanowire solar cell is proposed in which a p-type Si semiconductor is grown in the shape of nanowire and in which an n-type Si semiconductor layer is then formed on the p-type Si semiconductor along the shape of the p-type Si semiconductor (see, for example, Japanese Patent Laid-Open Publication No. 2008-53730). In the solar cell, a porous template layer made of nanoporous aluminum oxide is formed on a glass substrate covered with a degenerately doped polycrystalline silicon film, and the p-type Si semiconductor is grown from the porous template layer.

The nanowire solar cell described in Japanese Patent Laid-Open No. 2008-53730 comprises a core shell structure, in which the nanowire of p-type Si semiconductor is used as the core and in which the n-type Si semiconductor layer is laminated, as the shell, on the nanowire of p-type Si semiconductor, and hence has a pn junction surface with an area larger than a light receiving area. However, in the nanowire solar cell, since the lower contact is formed after the nanowire of p-type Si semiconductor is formed by using the pore of the template layer, the lower contact is limited to a metal contact or a transparent electrode, and single-crystal semiconductor material cannot be used for the lower contact.

Further, since the nanowire of p-type Si semiconductor is formed by a VLS method (vapor-liquid-solid processes) using a metal catalyst, and since the metal catalyst remains at both ends of the nanowire, a semiconductor cannot be joined to the nanowire so as to be used as the lower contact. In this case, the nanowire with no remaining metal catalyst can be formed by a method, such as a method of removing the metal catalyst by etching after the VLS growth process, and an electrochemical deposition method. However, in the nanowire solar cell, the lower contact made of a planar single crystal semiconductor cannot be formed by the epitaxial growth process after the formation of the nanowire.

Further, in Japanese Patent Laid-Open No. 2008-53730, it is described that, in the nanowire solar cell, the porous template layer is located on the substrate and that the lower contact is provided by the substrate. However, the need for epitaxial growth is not described. Further, there is a problem that, according to the VLS method, the metal material remains in the boundary surface between the substrate and the nanowire. When the electrochemical deposition method, and the like, is used, no metal material remains in the boundary surface between the substrate and the nanowire. However, there is no guarantee that, when the crystal of the substrate and the crystal the nanowire are connected to each other, their orientation is maintained.

Further, a nanowire solar cell is proposed in which a Ta₂N layer is formed on a metal foil substrate made of stainless steel, in which a nanowire of p-type Si semiconductor is formed on the Ta₂N layer, and in which an n-type Si semiconductor layer is formed on the p-type Si semiconductor along the shape of the p-type Si semiconductor (see, for example, L. Tsakalakos, J. Balch, J. Fronheiser, B. A. KoreVaar, O. Sulima and J. Rand, “Silicon nanowire solar cells”, APPLIED PHYSICS LETTERS 91, 233117 (2007)). The nanowire of p-type Si semiconductor is formed on the Ta₂N layer by a VLS method using a metal catalyst. However, as described above, the VLS method has a problem that the metal catalyst remains at both ends of the nanowire.

Further, in any of the above described solar cells, it is not possible to obtain practical electric power. For example, the solar cell described in the above described document has a disadvantage that, in the state where Voc is 0.13 V, where Isc is 3 mA/cm², and where FF is 0.28, η is only 0.06%.

### SUMMARY OF THE INVENTION

An object of the present invention is to eliminate such disadvantages, to provide a solar cell which is capable of configuring a device with a plurality of nanowire semiconductors arranged in an array form, and which is capable of obtaining practical electric power and effectively collecting excitons, and to provide a manufacturing method of the solar cell.

To this end, the present invention provides a nanowire solar cell which includes a semiconductor substrate and a plurality of nanowire semiconductors grown on the semiconductor substrate to form pn junctions, and which is featured by comprising: a transparent insulating material filled in the gap between the plurality of nanowire semiconductors; an electrode which is continuously provided on the transparent insulating material to cover the end portion of the plurality of nanowire semiconductors, the end portion being opposite to the semiconductor substrate, and is connected to the plurality of nanowire semiconductors; and a passivation layer which is provided, along the surface of the plurality of nanowire semiconductors, between the plurality of nanowire semiconductors and the transparent insulating material and between the plurality of nanowire semiconductors and the electrode, so as to prevent recombination of excitons.

In the nanowire solar cell having the above described configuration according to the present invention, the area of the contact interface between the nanowire semiconductors and the electrode connected to the nanowire semiconductors can be reduced by the provision of the transparent insulating material, to thereby reduce the number of defects caused on a current path by a photovoltaic force. As a result, the recombination sites resulting from the defects in the boundary surface can be easily saturated, so that the photoelectric conversion efficiency can be improved and practical electric power can be obtained.

Further, in the nanowire solar cell according to the present invention, since the passivation layer for preventing the recombination of electrons is provided along the surface of the nanowire semiconductor, the surface recombination of electrons attracted to the surface side of the nanowire semiconductor is prevented, so that the excitons can be effectively collected.

Further, in the nanowire solar cell according to the present invention, it is preferred that the semiconductor substrate and the nanowire semiconductor are made of one single crystal. When the semiconductor substrate and the nanowire semiconductor are made of one single crystal, it is possible to eliminate the contamination by the metal catalyst, the defect of the crystal grain boundary, and the like, in the nanowire semiconductor, the defect in the boundary surface between the semiconductor substrate and the nanowire semiconductor, and the like. Therefore, with the nanowire solar cell according to the present invention in which the semiconductor substrate and the nanowire semiconductor are made of one single crystal, the electric resistance per unit area can be reduced, so that the photoelectric conversion efficiency can be further improved.

The nanowire solar cell according to the present invention can be advantageously manufactured by a manufacturing method comprising the steps of: covering a part of the surface of a semiconductor substrate with an amorphous film; forming a plurality of nanowire semiconductors by epitaxially growing a crystal made of the same material as the material of the semiconductor substrate on the surface of the semiconductor substrate, the surface being exposed from the amorphous film; forming a passivation layer for preventing recombination of excitons by epitaxially growing, on the surface of the plurality of nanowire semiconductors, a crystal forming a type 1 heterojunction with the nanowire semiconductor; filling a transparent insulating material in the gap between the plurality of nanowire semiconductors; and forming an electrode which is continuously provided on the transparent insulating material to cover the end portion of the plurality of nanowire semiconductors, the end portion being opposite to the semiconductor substrate, and is connected to the plurality of nanowire semiconductors.

In the manufacturing method, the exposed portion of the semiconductor substrate can be freely controlled by using a lithography technique or a nano-imprint technique for the amorphous film. Further, when the growth direction of the nanowire semiconductor and the orientation of the substrate are suitably selected, it is possible to eliminate the error in cutting the semiconductor substrate and to obtain a nanowire semiconductor completely perpendicular to the semiconductor substrate. Further, in the manufacturing method, the nanowire semiconductor can also be epitaxially grown in the lateral direction by changing the epitaxial growth condition during the epitaxial growth.

Therefore, according to the manufacturing method, a device can be configured by arranging a plurality of nanowire semiconductors in a high density array, and hence the optical absorption efficiency can be improved.

Further, it is preferred that the manufacturing method further comprises the step of exposing, after embedding the plurality of nanowire semiconductors in the transparent insulating material, the tip of the plurality of nanowire semiconductors by removing a part of the transparent insulating material, so as to thereby allow the transparent insulating material to be filled in the gap between the plurality of nanowire semiconductors. According to the manufacturing method, the transparent insulating material can be easily filled in the gap between the plurality of nanowire semiconductors by the process.

Further, it is preferred that the manufacturing method further comprises the step of forming, after forming the passivation layer, a protective coating layer for shielding the passivation layer from the atmosphere on the surface of the passivation layer. In the manufacturing method, when the protective coating layer is formed, it is possible to prevent that the passivation layer is oxidized by being brought into contact with the atmosphere during the manufacturing process.

### BRIEF DESCRIPTION OF THE DRAWINGS

FIG. 1 is an explanatory sectional view showing a structure of a configuration example of a nanowire solar cell according to the present invention;

FIG. 2 is a graph showing a relationship (I-V curve) between the voltage and the current density in the nanowire solar cell according to the present invention; and

FIG. 3 is a graph showing a relationship between the external quantum efficiency in the nanowire solar cell according to the present invention and the wavelength of irradiation light.

### DETAILED DESCRIPTION OF THE PREFERRED EMBODIMENTS

Next, an embodiment according to the present invention will be described with reference to the accompanying drawings.

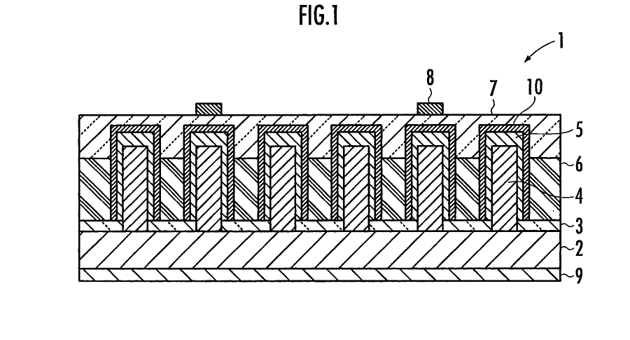

First, a nanowire solar cell 1 of a present embodiment will be described with reference to FIG. 1. The nanowire solar cell 1 comprises an amorphous SiO₂ coating 3 formed on an InP (111) A substrate 2, and a nanowire p-type InP semiconductor 4 formed on the InP (111) A substrate 2 exposed from the amorphous SiO₂ coating 3. The nanowire p-type InP semiconductor 4 comprises an n-type InP semiconductor 5 along the surface shape thereof, and an i-type InP semiconductor (not shown) is provided between the p-type InP semiconductor 4 and the n-type InP semiconductor 5. Here, the nanowire solar cell 1 has a core shell structure in which the p-type InP semiconductor 4 is used as the core and in which the i-type InP semiconductor and the n-type InP semiconductor 5 are used as the shell.

The nanowire solar cell 1 comprises a transparent insulating material 6 filled in the gap between the plurality of nanowires formed of the p-type InP semiconductor 4, the i-type InP semiconductor, and the n-type InP semiconductor 5, and also comprises a transparent electrode 7 continuously provided on the transparent insulating material 6. The transparent electrode 7 covers the end portion of the nanowire-shaped portions formed of the p-type InP semiconductor 4, the i-type InP semiconductor, and the n-type InP semiconductor 5, the end portion being opposite to the InP (111) A substrate 2, and is connected to the p-type InP semiconductor 4, the i-type InP semiconductor, and the n-type InP semiconductor 5.

As the transparent insulating material 6, it is possible to list, for example, a material made of BCB resin (bis-benzocyclobutene, made by Dow Chemical Co.). Further, as the transparent electrode 7, it is possible to list, for example, an electrode made of an indium tin oxide (ITO), and the like.

Further, the nanowire solar cell 1 comprises collecting electrodes 8 formed on the transparent electrode 7, and a rear surface electrode 9 provided on the surface of the InP (111) A substrate 2, the surface being opposite to the amorphous SiO₂ coating 3. As the collecting electrode 8, it is possible to list, for example, an electrode formed by successively vapor-depositing Ag and Ni. Further, as the rear surface electrode 9, it is possible to list, for example, an electrode formed by vapor-depositing an Au—Zn alloy.

Further, the nanowire solar cell 1 comprises a passivation layer 10 formed between the n-type InP semiconductor 5 and the transparent insulating materials 6, and between the n-type InP semiconductor 5 and the transparent electrodes 7, along the surface of the nanowire-shaped portion formed of the p-type InP semiconductor 4, the i-type InP semiconductor, and the n-type InP semiconductor 5. As the material of the passivation layer 10, it is possible to use a material which has a band gap larger than the band gap of the pn junction formed by the nanowire semiconductor, and which forms a type 1 heterojunction with the nanowire semiconductor.

As in the case of the present embodiment in which the nanowire semiconductor is formed of the p-type InP semiconductor 4 and the n-type InP semiconductor 5, a material which has a band gap larger than the band gap of the pn junction of the nanowire semiconductor and which forms a type 1 heterojunction with InP can be used as the material of the passivation layer 10. As the material which forms the type 1 heterojunction, AlP or AlInP can be used in the present embodiment.

Further, in the case where the nanowire semiconductor is made of GaAs, it is possible to use AlP, AlInP, AlAs, or AlGaAs as the material for forming the type 1 heterojunction.

The passivation layer 10 comprises, on the surface thereof, a surface cap layer (not shown) as a protective coating layer. As the material of the surface cap layer, an n-type InP semiconductor can be used to prevent the oxidization of Al of the passivation layer 10 due to the contact of the passivation layer 10 with the atmosphere during the manufacturing process.

Note that, in a heterojunction formed of materials A and B, when the work function of the material A with respect to the vacuum level is set as q_{χA}, and the bandgap energy is set as Eg_{A}, and when the work function of the material B with respect to the vacuum level is set as q_{χB}, and the band gap energy is set as Eg_{B}, the height C of the conduction band and the height V of the valence band are expressed by the following expressions.

C=q_{χB}−q_{χA}

V=(Eg_{B}−q_{χB})−(Eg_{A}−q_{χA})

At this time, the heterojunction having the relationship of C×V<0 is referred to as the type 1 heterojunction.

Next, the manufacturing method of the nanowire solar cell 1 shown in FIG. 1 will be described.

First, the InP (111) A substrate 2 which is a p-type semiconductor substrate is washed, and then the amorphous SiO₂ coating 3 is formed in the thickness of about 30 nm on the surface of the InP (111) A substrate 2 by using an RF sputtering apparatus provided with an SiO₂ target.

Next, a positive resist is applied on the amorphous SiO₂ coating 3. Then, the InP (111) A substrate 2 is set in an EB drawing apparatus, and a pattern is drawn on the positive resist. The pattern is formed by arranging, for example, circular holes having a diameter of 100 nm in a triangular lattice shape with a pitch of 400 nm.

After the drawing, the resist is developed, and the InP (111) A substrate 2 is then immersed in a BHF solution diluted to 50 times, so that SiO₂ in the circular holes is removed through etching. After the etching, the resist is removed.

Next, the InP (111) A substrate 2 with the amorphous SiO₂ coating 3 formed thereon is set in an MOVPE apparatus. Then, the gas in the chamber is replaced with H₂ gas after the chamber is evacuated, and the flow rate and the exhausting rate are adjusted so that the total pressure is stabilized at 0.1 atm.

Next, while the mixed gas of TBP (tertiarybutylphosphine) and the carrier gas (H₂) (total pressure: 0.1 atm, TBP partial pressure: 1.1×10⁻⁴ atm) are made to flow, the temperature is raised until the substrate temperature becomes 630° C. Then, after the substrate temperature reaches 630° C., the flowing gas is changed to the mixed gas of TMI (trimethylindium), DEZ (diethylzinc), TBP and the carrier gas. The mixed gas is introduced into the reaction chamber, and the p-type InP semiconductor 4 is epitaxially grown in the shape of nanowire. In the state where the total pressure is maintained at 0.1 atm, the flow rate of each organic metal gas is adjusted so that the partial pressure of TMI becomes 3×10⁻⁶ atm, the partial pressure of DEZ becomes 1×10⁻⁶ atm and the partial pressure of TBP becomes 5.5×10⁻⁵ atm. After 10 minutes, the flowing gas is changed to the mixed gas of TBP and the carrier gas (total pressure: 0.1 atm, TBP partial pressure: 1.1×10⁻⁴ atm), and the epitaxial growth of the p-type InP semiconductor 4 is ended.

Next, the substrate temperature is lowered from 630° C. to 550° C. while the mixed gas of TBP and the carrier gas are made to flow. After the substrate temperature reaches 550° C., the flowing gas is changed to the mixed gas of TMI, TBP, SiH₄ and the carrier gas. The mixed gas is introduced into the reaction chamber for 10 minutes, and the n-type InP semiconductor 5 is epitaxially grown on the surface of the p-type InP semiconductor 4. In the state where the total pressure is maintained at 0.1 atm, the flow rate of each organic metal gas is adjusted so that the partial pressure of TMI becomes 3×10⁻⁶ atm, the partial pressure of SiH₄ becomes 1×10⁻⁶ atm, and the partial pressure of TBP becomes 1.1×10⁻⁴ atm. After 10 minutes, the flowing gas is changed to the mixed gas of TBP and the carrier gas (total pressure: 0.1 atm, TBP partial pressure: 1.1×10⁻⁴ atm), and the epitaxial growth of the n-type InP semiconductor 5 is ended.

Next, while the substrate temperature is maintained at 550° C., the flowing gas is changed to the mixed gas of TMA (trimethylaluminum), TMI, TBP, SiH₄ and the carrier gas. The mixed gas is introduced into the reaction chamber for 2 minutes, and the n-type AlInP passivation layer 10 is epitaxially grown on the surface of the n-type InP semiconductor 5. In the state where the total pressure is maintained at 0.1 atm, the flow rate of each organic metal gas is adjusted so that the partial pressure of TMA becomes 3.3×10⁻⁷ atm, the partial pressure of TMI becomes 3×10⁻⁶ atm, the partial pressure of SiH₄ becomes 1×10⁻⁶ atm, and the partial pressure of TBP becomes 1.1×10⁻⁴ atm. After 2 minutes, the flowing gas is changed to the mixed gas of TBP and the carrier gas (total pressure: 0.1 atm, TBP partial pressure: 1×10⁻⁴ atm), and the epitaxial growth of the n-type AlInP passivation layer 10 is ended.

Next, the flowing gas is changed to the mixed gas of TMI, TBP, SiH₄ and the carrier gas. The mixed gas is introduced into the reaction chamber for 1 minute, and the n-type InP surface cap layer (not shown) is epitaxially grown on the surface of the n-type AlInP passivation layer 10. In the state where the total pressure is maintained at 0.1 atm, the flow rate of each organic metal gas is adjusted so that the partial pressure of TMI becomes 3×10⁻⁶ atm, the partial pressure of SiH₄ becomes 1×10⁻⁶ atm, and the partial pressure of TBP becomes 1.1×10⁻⁴ atm. After 1 minute, the flowing gas is changed to the mixed gas of TBP and the carrier gas (total pressure: 0.1 atm, TBP partial pressure: 1×10⁻⁴ atm), and the epitaxial growth of the n-type InP surface cap layer is ended.

By the formation of the n-type InP surface cap layer, the n-type AlInP passivation layer 10 is shielded from the atmosphere during the manufacturing process, so as to prevent oxidation of Al in the n-type AlInP passivation layer 10 by the atmosphere.

After the epitaxial growth of the n-type InP surface cap layer is ended, the InP (111) A substrate 2 is cooled while the mixed gas of TBP and the carrier gas (total pressure: 0.1 atm, TBP partial pressure: 1.1×10⁻⁴ atm) are made to flow, and is then taken out.

Thereby, it is possible to obtain a nanowire semiconductor having the core shell structure in which the p-type InP semiconductor 4 is used as the core and in which the n-type InP semiconductor 5 is used as the shell. Note that when the p-type InP semiconductor 4 and the n-type InP semiconductor 5 are epitaxially grown, the p-type InP semiconductor 4 and the n-type InP semiconductor 5 may not be formed into a cylindrical shape but may be formed into a hexagonal columnar shape. In this case, it is assumed that the diameter of the nanowire semiconductor is the diameter of the inscribed circle of the hexagon of the cross section of the nanowire semiconductor.

Next, BCB resin (made by the Dow Chemical Co.) is applied by a spin coating method on the side of the p-type InP semiconductor 4 and the n-type InP semiconductor 5 of the InP (111) A substrate 2 on which the p-type InP semiconductor 4 and the n-type InP semiconductor 5 are epitaxially grown in the shape of nanowire. Next, the BCB resin is cured by being subjected to the anneal treatment at the temperature of 250° C. for 1 hour under the inert gas atmosphere, so that the transparent insulating material 6 made of the cured BCB resin is formed.

Next, the excessively applied BCB resin is etched by RIE processing using the mixed gas of CF₄ and O₂, so that the tip of the nanowire semiconductors 4 and 5 is exposed by 150 nm. Next, an RF sputtering apparatus provided with an ITO target is used to film-form the transparent electrode 7 made of ITO on the transparent insulating material 6. The transparent electrode 7 is continuously provided on the transparent insulating material 6, and also covers the nanowire semiconductors 4 and 5 so as to be connected to the nanowire semiconductors 4 and 5.

Next, an AuZn alloy is vapor-deposited on the surface of the InP (111) A substrate 2, the surface being opposite to the amorphous SiO₂ coating 3, and is subjected to the anneal treatment at the temperature of 400° C. for 2 minutes, so that the rear surface electrode 9 is formed. Further, Ag and Ni are successively vapor-deposited on a part of the surface of the transparent electrode 7 made of ITO, so as to form the collecting electrode 8, and thereby the nanowire solar cell 1 is obtained.

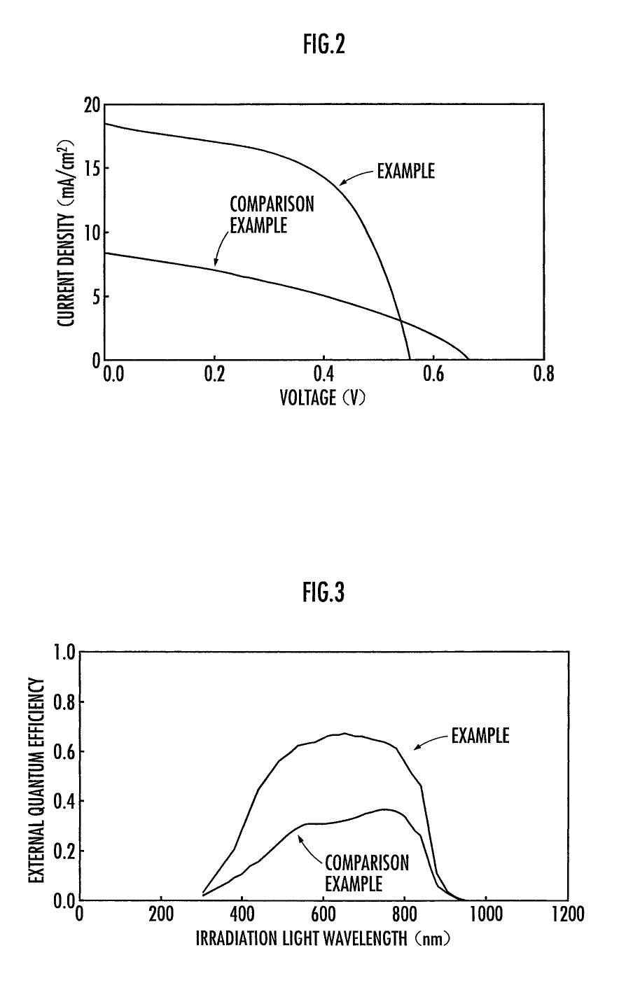

Next, the performance of the nanowire solar cell 1 (example), in which the nanowire semiconductor, having the core shell structure using the p-type InP semiconductor 4 as the core and the n-type InP semiconductor 5 as the shell, was formed to have the height of 1000 nm and the diameter of 250 nm, was evaluated. The performance was evaluated based on the I-V curve of the nanowire solar cell 1 obtained at the time when the nanowire solar cell 1 was irradiated with artificial solar light of AM 1.5. The performance of the nanowire solar cell 1 is shown in Table 1, and the I-V curve is shown in FIG. 2.

Further, as an index representing the degree of collection of electrons (excitons) generated by the light irradiation, a relationship between the external quantum efficiency represented by the ratio of the number of photons of the irradiation light to the number of outputted electrons, and the wavelength of the irradiation light was measured. The measurement result is shown in FIG. 3.

Next, the performance of a nanowire solar cell (comparison example), which was formed in completely the same manner as the present embodiment except that any of the passivation layer 10 and the surface cap layer was not formed, was measured in completely the same manner as in the nanowire solar cell 1 (example). The performance of the nanowire solar cell of the comparison example is shown in Table 1, and the I-V curve of the nanowire solar cell of the comparison example is shown in FIG. 2.

Further, the relationship between the external quantum efficiency and the wavelength of irradiation light was measured about the nanowire solar cell of the comparison example. The measurement result is shown in FIG. 3.

TABLE 1

| | | Comparison |
|---|---|---|
| | Example | example |
| Voc (V) | 0.560 | 0.670 |
| Isc | 18.657 | 8.365 |
| (mA/cm²) | | |
| FF | 0.552 | 0.569 |
| η (%) | 5.77 | 2.04 |

It is clearly seen from Table 1 and FIG. 2 that, with the nanowire solar cell 1 according to the present embodiment comprising the passivation layer 10, the conversion efficiency can be improved by more than twice the conversion efficiency of the nanowire solar cell of the comparison example not comprising the passivation layer 10, and hence the practical electric power can be obtained.

Further, it is clearly seen from FIG. 3 that, in the nanowire solar cell 1 according to the present embodiment comprising the passivation layer 10, the external quantum efficiency is more than twice the external quantum efficiency of the nanowire solar cell of the comparison example not comprising the passivation layer 10, and hence the photoexcited electrons (excitons) can be efficiently collected. It may be configured that an n-type GaInP can be used as the passivation layer 10 in place of the n-type AlInP.

Note that the present embodiment is configured such that the nanowire semiconductors 4 and 5 are grown on the InP (111) A substrate 2, and such that the transparent electrode 7 made of ITO is film-formed on the transparent insulating material 6. However, it may also be configured such that, in place of the InP (111) A substrate 2 used in the present embodiment, a transparent electrodes made of a material, such as n-type InGaP or p-type InGaP, is used as the substrate, and such that the nanowire semiconductors 4 and 5 are grown on the substrate. In this case, in place of the transparent electrode 7 made of ITO, a metal electrode is film-formed by sputtering, or the like, on the transparent insulating material 6. With this configuration, it is possible to obtain a solar cell which receives light from the side of the substrate made of the transparent electrode.

Further, when the transparent electrode made of a material, such as p-type InGaP, is used as the substrate, and when the nanowire semiconductors 4 and 5 are grown on the substrate, the transparent electrode 7 made of ITO may also be film-formed on the transparent insulating material 6 similarly to the present embodiment.

What is claimed is:

1. A nanowire solar cell including a semiconductor substrate and a plurality of nanowire semiconductors grown on the semiconductor substrate to form pn junctions, the nanowire solar cell comprising:
a transparent insulating material which is filled in a gap between the plurality of nanowire semiconductors;
an electrode which is continuously provided on the transparent insulating material to cover the end portion of the plurality of nanowire semiconductors, the end portion being opposite to the semiconductor substrate, and is connected to the plurality of nanowire semiconductors; and
a passivation layer which is provided, along the surface of the plurality of nanowire semiconductors, between the plurality of nanowire semiconductors and the transparent insulating material and between the plurality of nanowire semiconductors and the electrode, so as to prevent recombination of excitons.

2. The nanowire solar cell according to claim 1, wherein the semiconductor substrate and the nanowire semiconductor are formed of one single crystal.

3. The nanowire solar cell according to claim 1, wherein the semiconductor substrate is formed of an InP (111) A substrate.

4. The nanowire solar cell according to claim 1, wherein the nanowire semiconductor comprises InP.

5. The nanowire solar cell according to claim 1, wherein the nanowire semiconductor comprises GaAs.

6. The nanowire solar cell according to claim 1, wherein the transparent insulating material comprises BCB (bis-benzocyclobutene) resin.

7. The nanowire solar cell according to claim 1, wherein the electrode comprises indium tin oxide.

8. The nanowire solar cell according to claim 1, wherein the passivation layer comprises a material which has a band gap larger than the pn junction formed by the nanowire semiconductor and forms a type 1 heterojunction with the nanowire semiconductor.

9. The nanowire solar cell according to claim 8, wherein, when the nanowire semiconductor comprises InP, the passivation layer comprises AlP or AlInP.

10. The nanowire solar cell according to claim 8, wherein, when the nanowire semiconductor comprises GaAs, the passivation layer comprises one kind of a compound selected from a group consisting of AlP, AlInP, AlAs, GaInP, and AlGaAs.

11. The nanowire solar cell according to claim 8, wherein the passivation layer comprises, on the surface thereof, a protective coating layer for shielding the passivation layer from the atmosphere.

12. A manufacturing method of a nanowire solar cell, comprising the steps of:
covering a part of the surface of a semiconductor substrate with an amorphous film;
forming a plurality of nanowire semiconductors by epitaxially growing a crystal made of the same material as the material of the semiconductor substrate on the surface of the semiconductor substrate, the surface being exposed from the amorphous film;
forming a passivation layer for preventing recombination of excitons by epitaxially growing, on the surface of the plurality of nanowire semiconductors, a crystal forming a type 1 heterojunction with the nanowire semiconductor;
filling a transparent insulating material in a gap between the plurality of nanowire semiconductors; and
forming an electrode which is continuously provided on the transparent insulating material to cover the end portion of the plurality of nanowire semiconductors, the end portion being opposite to the semiconductor substrate, and is connected to the plurality of nanowire semiconductors.

13. The manufacturing method of the nanowire solar cell according to claim 12, wherein the semiconductor substrate comprises an InP (111) A substrate.

14. The manufacturing method of the nanowire solar cell according to claim 12, wherein the amorphous film comprises amorphous SiO₂.

15. The manufacturing method of the nanowire solar cell according to claim 14,
wherein the amorphous film is formed by a method comprising the steps of:
forming an amorphous SiO₂ film on the semiconductor substrate;
applying a positive resist on the amorphous SiO₂ film;
drawing, on the positive resist, a pattern of a plurality of circular holes arranged in a triangular lattice shape;
developing the positive resist; and
removing the amorphous SiO₂ in the circular holes by etching.

16. The manufacturing method of the nanowire solar cell according to claim 12, wherein the nanowire semiconductor comprises InP.

17. The manufacturing method of the nanowire solar cell according to claim 12, wherein the nanowire semiconductor comprises GaAs.

18. The manufacturing method of the nanowire solar cell according to claim 12, wherein the transparent insulating material comprises BCB (bis-benzocyclobutene) resin.

19. The manufacturing method of the nanowire solar cell according to claim 12, further comprising the step of, after embedding the plurality of nanowire semiconductors in the transparent insulating material, exposing the tip portion of the plurality of nanowire semiconductors by removing a part of the transparent insulating material, so as to thereby allow the transparent insulating material to be filled in the gap between the plurality of nanowire semiconductors.

20. The manufacturing method of the nanowire solar cell according to claim 19, wherein a part of the transparent insulating material is removed by an RIE (Reactive Ion Etching) method.

21. The manufacturing method of the nanowire solar cell according to claim 12, wherein the electrode comprises indium tin oxide.

22. The manufacturing method of the nanowire solar cell according to claim 12, wherein the passivation layer comprises a material which has a band gap larger than the pn junction formed by the nanowire semiconductor and forms a type 1 heterojunction with the nanowire semiconductor.

23. The manufacturing method of the nanowire solar cell according to claim 12, wherein, when the nanowire semiconductor comprises InP, the passivation layer comprises AlP or AlInP or GaInP.

24. The manufacturing method of the nanowire solar cell according to claim 12, wherein, when the nanowire semiconductor comprises GaAs, the passivation layer comprises one kind of a compound selected from a group consisting of AlP, AlInP, AlAs, GaInP, and AlGaAs.

25. The manufacturing method of the nanowire solar cell according to claim 12, further comprising the step of forming, after forming the passivation layer, a protective coating layer for shielding the passivation layer from the atmosphere on the surface of the passivation layer.
